(19) United States
(12) Patent Application Publication
(10) Pub. No.: US 2007/0269738 A1
(43) Pub. Date: Nov. 22, 2007

(54) Photosensitive Film, Photosensitive Film Laminate and Photosensitive Film Roll

(75) Inventors: Katsutoshi Itagaki, Ibaraki (JP); Naoki Sasahara, Ibaraki (JP); Masanori Shindou, Ibaraki (JP); Naoto Okada, Ibaraki (JP)

Correspondence Address: GRIFFIN & SZIPL, PC, SUITE PH-1, 2300 NINTH STREET, SOUTH, ARLINGTON, VA, 22204, US

(73) Assignee: HITACHI CHEMICAL COMPANY, LTD., Tokyo (JP)

(21) Appl. No.: 11/572,947

(22) PCT Filed: Jul. 28, 2005
(86) PCT No.: PCT/JP05/13822

§ 371 Date: Jan. 30, 2007

(30) Foreign Application Priority Data
Jul. 30, 2004 (JP) 2004-223533

(51) Int. Cl. G03F 7/004; G03F 7/095

(52) U.S. Cl. 430/270.1

(57) ABSTRACT

The photosensitive film of the invention is a photosensitive film comprising a photosensitive resin layer (30) on a support film (1), characterized in that the photosensitive resin layer (30) is prepared by laminating two or more layers including a facing photosensitive resin layer (2) having a facing surface that faces one surface of the support film (1) and an opposite photosensitive resin layer (3) having an opposing surface (F2) on the side of the photosensitive resin layer (30) opposite the facing surface, and in that no protective film is present on the photosensitive resin layer (30) and the film can be wound into a roll.

### TECHNICAL FIELD

The present invention relates to a photosensitive film, to a photosensitive film laminate and to a photosensitive film roll.

### BACKGROUND ART

Resist materials used for etching, plating and the like in the field of manufacturing conventional printed circuit boards include widely employed photosensitive films obtained using photosensitive resin compositions with supports (support films) and protective films.

Printed circuit boards are manufactured by a process in which a photosensitive film is laminated on a copper board and subjected to pattern exposure, after which the cured sections are removed with a developing solution, etching or plating treatment is carried out to form a pattern, and then the cured sections are released and removed from the board.

Conventionally known structures for photosensitive films include three-layer structures comprising a support film, photosensitive resin layer and protective film, and two-layer structures comprising a silicone-based or non-silicone-based release-treated support film and a photosensitive resin layer (see Patent documents 1-5).

Also, photosensitive films have conventionally had a sandwich structure obtained by attaching a protective film to a photosensitive resin layer formed by coating and drying a photosensitive resin composition on a transparent support film. The continuous-length photosensitive film is wound into a coil around a core made of a paper tube, wooden tube, plastic tube or the like for handling, including storage and transport.

Such photosensitive films are used to form microcircuits in the fields of printed circuit board manufacturing and metal precision working, and the following methods are commonly employed. First, the protective film is released from the photosensitive film and the photosensitive resin layer is contact bonded (laminated) onto a base material in direct contact therewith. A patterned negative film is then adhered onto the support film and exposed to irradiation (exposure) with active light rays (usually ultraviolet rays). Next, an organic solvent or aqueous alkali solution is sprayed and a resist pattern is formed by removing the unwanted sections (development), after which etching is performed using an aqueous copper(II) chloride solution or the like.

The support film of the photosensitive film is usually a polyester film such as a PET (polyethylene terephthalate) film, and the protective film is usually a polyolefin film such as a PE (polyethylene) film.

[Patent document 1] Japanese Unexamined Patent Publication HEI No. 09-230580

[Patent document 2] Japanese Unexamined Patent Publication HEI No. 11-237732

[Patent document 3] Japanese Unexamined Patent Publication No. 2003-195491

[Patent document 4] Japanese Unexamined Patent Publication No. 2003-195492

[Patent document 5] Japanese Unexamined Patent Publication HEI No. 06-236026

### DISCLOSURE OF THE INVENTION

### Problems to be Solved by the Invention

However, since the protective film is usually removed during lamination, it is unnecessary for use and constitutes a problem for disposal as waste. Moreover, using a protective film increases the production cost for the photosensitive film.

A polyolefin film used as the protective film is produced by heat-fusion of the raw materials, kneading, extrusion, biaxial stretching or casting. Protective films such as polyolefin films generally contain non-fused and thermally degraded sections known as “fish eyes”. The fish eye sizes generally have diameters (φ) of 30-600 μm, and protrude at heights of 2-40 μm from the film surface. The fish eye protrusions are therefore transferred to the photosensitive resin layer as depressions in the photosensitive resin layer, and produce air voids on the board after lamination. These air voids are formed in correlation with the photosensitive resin layer thickness, occurring more readily with thinner photosensitive resin layer thicknesses, and are a cause of pattern defects and wire breakage in the subsequent image formation steps of exposure, development and etching.

As mentioned above, using an protective film leads to a variety of problems, and therefore a “protective film-less” type photosensitive film with no protective film has been desired. Moreover, in light of environmental problems caused by waste products and the demand for reduced costs of photosensitive films, it has been ardently desired to provide a photosensitive film that does not require the use of a protective film, and that is separable in terms of function.

As such “protective film-less” type photosensitive films there are known the aforementioned two-layer structure comprising a silicone-based or non-silicone-based release-treated support film and a photosensitive resin layer. When such a photosensitive film is wound or stacked, the photosensitive resin layer is laminated over itself through the release layer, and therefore the photosensitive resin laminated body does not adhere to itself and handling for use is facilitated. However, when a photosensitive film using such a release-treated support film is stored with the release layer in contact with the photosensitive resin layer, the components in the release layer migrate into the photosensitive resin layer, causing the problem of reduced adhesiveness of the resist pattern. Moreover, because of the high cost of the material used as the release layer, the overall cost of the photosensitive film is undesirably increased.

It is an object of the present invention to provide a protective film-less type photosensitive film that does not require the use of a protective film or a release treated support film.

### Means for Solving the Problems

In order to achieve the object stated above, the invention provides [1] a photosensitive film comprising a photosensitive resin layer on a support film, wherein the photosensitive resin layer is prepared by laminating two or more layers including a facing photosensitive resin layer having a facing surface that faces one surface of the support film and an opposite photosensitive resin layer having an opposing surface on the side of the photosensitive resin layer opposite the facing surface, and wherein the photosensitive film has no protective film on the photosensitive resin layer and can be wound up into a roll.

Here, the “protective film” serves to protect the photosensitive resin layer during storage of the photosensitive film, and it will usually be a film composed of a polyolefin film such as polyethylene, polypropylene or the like.

The photosensitive film of the invention preferably has one surface of the photosensitive film serving as the aforementioned photosensitive resin layer side. That is, the layer situated furthest from the support film in the photosensitive film preferably serves as the aforementioned opposite photosensitive resin layer.

The invention further provides [2] a photosensitive film according to [1] above, wherein the aforementioned one surface of the support film contacts with the aforementioned facing surface of the facing photosensitive resin layer, and wherein the adhesive force PU (units: N/m) between the aforementioned one surface of the support film and the aforementioned facing surface of the facing photosensitive resin layer and the adhesive force PT (units: N/m) between the opposite support surface on the side of the support film opposite the aforementioned one surface and the aforementioned opposing surface of the opposite photosensitive resin layer satisfy the condition represented by inequality (1) below.
1.5≦(PU/PT)≦10.0 (1)

The invention still further provides [3] a photosensitive film according to [1] or [2] above, wherein the facing photosensitive resin layer and opposite photosensitive resin layer each comprise a binder polymer, and wherein the binder polymer in the opposite photosensitive resin layer has a higher glass transition temperature (Tg) than the binder polymer in the facing photosensitive resin layer.

The invention still further provides [4] a photosensitive film according to [1] to [3] above, wherein the facing photosensitive resin layer and opposite photosensitive resin layer each comprise a binder polymer, and wherein the binder polymer in the opposite photosensitive resin layer contains styrene or a styrene derivative as a copolymerizing component.

The invention still further provides [5] a photosensitive film according to [1] to [4] above, wherein the facing photosensitive resin layer and opposite photosensitive resin layer each comprise a binder polymer, and wherein the binder polymer in the opposite photosensitive resin layer has a lower weight-average molecular weight than the binder polymer in the facing photosensitive resin layer.

The invention still further provides [6] a photosensitive film according to any one of [1] to [5] above, wherein the support film consists of a single layer or a plurality of laminated layers.

The invention still further provides [7] a photosensitive film according to any one of [1] to [6] above, wherein both sides of the support film have a maximum surface roughness of no greater than 3000 nm.

The invention still further provides [8] a photosensitive film according to any one of [1] to [7] above, wherein the thickness of each layer composing the photosensitive resin layer is 1-75 μm.

The invention still further provides [9] a photosensitive film according to any one of [1] to [8] above, wherein two or more of the layers composing the photosensitive resin layer are obtained simultaneously by multilayer coating or multilayer extrusion molding.

The invention still further provides [10] a photosensitive film laminate obtained by laminating a photosensitive film according to any one of [1] to [9] above.

The invention still further provides [11] a photosensitive film roll obtained by winding a photosensitive film according to any one of [1] to [9] above into a roll form around a core.

The invention still further provides [12] a photosensitive film roll according to [11] above, wherein after the photosensitive resin layer of the photosensitive film roll has been laminated on a copper-clad laminate under conditions with a laminating temperature of 110° C., a pressure of 0.3 MPa and a laminating speed of 3 m/min, and the entire surface of the photosensitive resin layer has been irradiated with active light rays of 100 mJ/cm² or greater within 30 minutes, the number of air voids of diameter 80 μm or greater generated between the photocured photosensitive resin layer and the copper-clad laminate surface is no greater than 10/m².

The invention still further provides [13] a photosensitive film roll according to [11] or [12] above, wherein the number of layers composing the photosensitive resin layer is 2-8.

### EFFECT OF THE INVENTION

The photosensitive film of the invention has properties that have been unobtainable with conventional photosensitive films, to allow formation of a protective film-less type photosensitive film. A protective film-less type can also reduce air void generation and waste emission during lamination onto boards. Moreover, since a longer photosensitive film roll product can be wound with the same mass without changing the rolling diameter, it is possible to reduce the mounting frequency of the photosensitive film on the laminating apparatus, and thereby minimize loss due to adjustment and the like and improve yield and productivity.

### BRIEF EXPLANATION OF THE DRAWINGS

FIG. 1 left is a cross-sectional view of a film-rolled photosensitive film of the invention also showing the laminated state, and FIG. 1 right is a magnified view of the laminated section.

FIG. 2 is a schematic cross-sectional view of a preferred embodiment of a protective film-less type photosensitive film of the invention.

FIG. 3 is a schematic view showing the photosensitive film of FIG. 2 wound into a roll.

FIG. 4 is a schematic cross-sectional view of another preferred embodiment of a protective film-less type photosensitive film of the invention.

FIG. 5 is a set of schematic cross-sectional views for an example of a support film.

FIG. 6 is a schematic diagram (longitudinal cross-section) illustrating an apparatus and method for measurement of the adhesive force of a test film.

FIG. 7 is a schematic (plan) view showing a procedure for preparation of a test piece for adhesive force measurement.

FIG. 8 shows a fused hole comprising three (large) holes: φ6 mm.

FIG. 9 shows a fused hole comprising three (small) holes: φ3 mm.

### EXPLANATION OF SYMBOLS

1: support film, 2: first photosensitive resin layer, 3: second photosensitive resin layer, 4: PET film (support film), 5: copper-clad laminate, 6: lifting table, 7: load, 8: clamp, 9: rubber seal, 10: board clamp, 11: double-sided tape, 12: photosensitive resin layer, 16: winding core, 21: first interlayer, 22: second interlayer, 30: photosensitive resin layer, 31: lubricant-containing film, 32: lubricant-free film, 33: functional film, 50,100,110: photosensitive films, 200: photosensitive film roll.

### BEST MODE FOR CARRYING OUT THE INVENTION

The photosensitive film of the invention is a photosensitive film comprising a photosensitive resin layer having at least a facing photosensitive resin layer and an opposite photosensitive resin layer on a support film, and it is characterized by having no protective film on the photosensitive resin layer and being able to be wound into a roll.

A protective film-less type photosensitive film of the invention will now be explained with reference to the accompanying drawings.

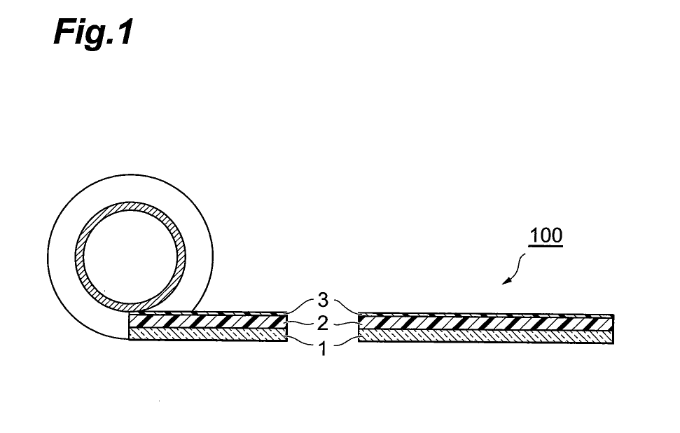

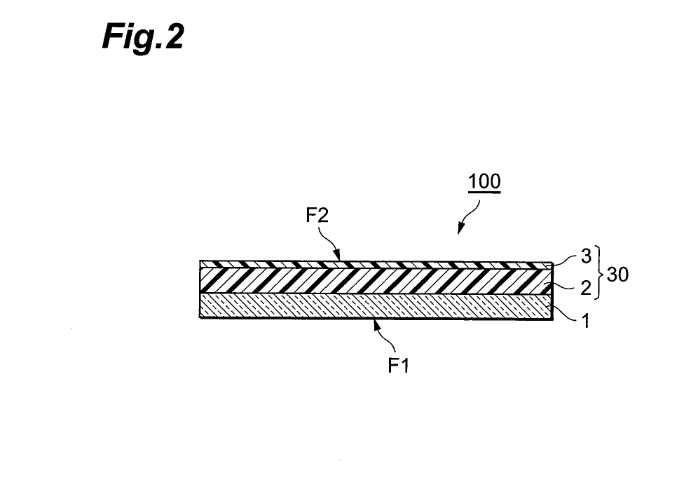

FIGS. 1 and 2 are schematic cross-sectional views of a preferred embodiment of a protective film-less type photosensitive film of the invention. As shown in FIGS. 1 and 2, the photosensitive film 100 has a construction comprising a support film 1, a first photosensitive resin layer (facing photosensitive resin layer) 2 formed on one surface of the support film 1, and a second photosensitive resin layer (opposite photosensitive resin layer) 3 formed on the first photosensitive resin layer 2. Here, the photosensitive resin layer 30 is composed of two layers, the first photosensitive resin layer 2 and the second photosensitive resin layer 3.

In this photosensitive film 100, the adhesive force PU (units: N/m) between the one surface of the support film 1 on which the first photosensitive resin layer 2 is formed and the facing surface facing the one surface of the photosensitive resin layer 30 (the surface on the side of the first photosensitive resin layer 2 which is in contact with the support film 1), and the adhesive force PT (units: N/m) between the opposite support surface F1 on the side of the support film 1 opposite the one surface and the opposing surface F2 on the side of the photosensitive resin layer 30 opposite the facing surface (the surface on the side of the second photosensitive resin layer 3 which is not in contact with the first photosensitive resin layer 2) preferably satisfy the condition represented by the following inequality (1).
1.5≦(PU/PT)≦10.0 (1)

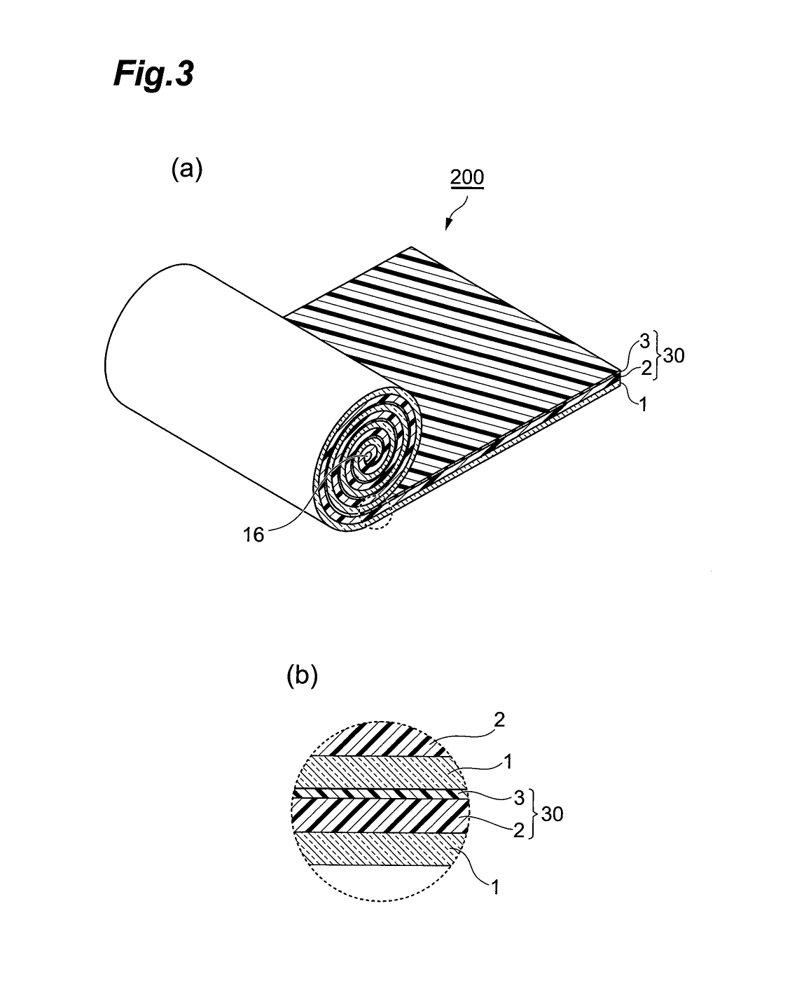

If the value of (PU/PT) for the photosensitive film 100 satisfies the condition represented by inequality (1) above, the photosensitive film 100 may be satisfactorily used after being stored, for example, in a roll-wound form or in a sheet-laminated form, even without having a protective film on the second photosensitive resin layer 3. FIG. 3(a) is a perspective view showing the photosensitive film 100 of FIG. 1 and FIG. 2 wound into a roll, and FIG. 3(b) is a magnified view of the section inside the dotted circle of FIG. 3(a). For storage, the photosensitive film 100 may have one end of the photosensitive film 100 wound around a winding core 16 as shown in FIG. 3(a), to be stored as a roll. Although the support film 1 and the second photosensitive resin layer 3 are in contact in this case as shown in FIG. 3(b), since the value of (PU/PT) satisfies the condition represented by inequality (1) above, the support film 1 and the second photosensitive resin layer 3 can be easily released when the photosensitive film 100 is released from the roll. Also, the support film 1 must be releasable from the first photosensitive resin layer 2 after the photosensitive film 100 has been laminated on the board or after irradiation with ultraviolet rays, and the adhesive force between the first photosensitive resin layer 2 and the support film 1 is preferably smaller than the adhesive force between the first photosensitive resin layer 2 and the second photosensitive resin layer 3. Thus, the photosensitive film 100 of the invention may be suitably stored and used as a photosensitive film laminate comprising a laminate of the photosensitive film 100, and especially as shown in FIG. 3, as a photosensitive film roll 200 comprising the photosensitive film 100 wound into a roll around a winding core 16.

From the viewpoint of achieving a more adequate effect, the value of (PU/PT) more preferably satisfies the condition represented by inequality (2) below, even more preferably satisfies the condition represented by inequality (3) below and most preferably satisfies the condition represented by inequality (4) below.
2.0≦(PU/PT)≦8.0 (2)
2.5≦(PU/PT)≦7.0 (3)
3.0≦(PU/PT)≦6.0 (4)

As a first method for achieving an adhesive force PT (units: N/m) between the opposite support surface F1 of the support film 1 and the opposing surface F2 of the second photosensitive resin layer 3 that is lower than the adhesive force PU (units: N/m) between the one surface of the support film 1 and the facing surface of the first photosensitive resin layer 2, and particularly for producing a (PU/PT) value that satisfies the condition represented by any one of inequalities (1) to (4) above, there may be mentioned a method of designing the Tg (glass transition temperature) of the binder polymer in the second photosensitive resin layer 3 to be higher than the Tg (glass transition temperature) of the binder polymer in the first photosensitive resin layer 2. The temperature difference between the Tg (glass transition temperature) of the binder polymer in the second photosensitive resin layer 3 and the Tg (glass transition temperature) of the binder polymer in the first photosensitive resin layer 2 is preferably at least 5° C., more preferably at least 10° C., even more preferably at least 15° C. and most preferably at least 20° C.

The Tg (glass transition temperature, units: ° C.) of the binder polymer of the invention is the value calculated from formula (5) below.
Tg=1/{Σ(Wᵢ/Tgᵢ)}−273 (5)
In formula (5), “i” is the subscript representing each polymerizable monomer component in the polymerizable monomer mixture of the binder polymer. Wᵢ represents the mass fraction of the polymerizable monomer i, and Tgᵢ represents the glass transition temperature (units: K) of a simple polymer of the polymerizable monomer i.

As a second method, there may be mentioned a method in which the binder polymer used in the second photosensitive resin layer 3 is one comprising styrene or a styrene derivative as a copolymerizing component.

As a third method, there may be mentioned a method in which the binder polymer used in the second photosensitive resin layer 3 is one having a weight-average molecular weight that is smaller than that of the binder polymer in the first photosensitive resin layer 2.

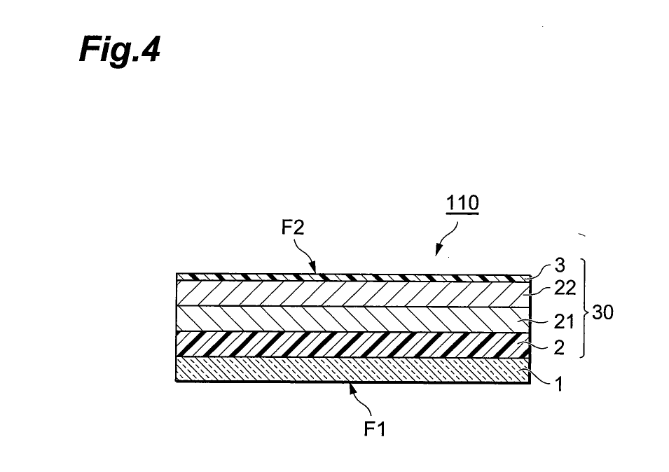

The photosensitive film of the invention need only have a structure wherein a photosensitive resin layer comprising at least a facing photosensitive resin layer and an opposite photosensitive resin layer are laminated on a support film, but preferably it has a structure with a photosensitive resin layer 30 composed of two layers laminated on a support film 1 as in the photosensitive film 100 shown in FIGS. 1 and 2, or a structure with a photosensitive resin layer composed of three or more layers laminated on a support film, which will facilitate construction of a protective film-less type photosensitive film such as described above. In the photosensitive film of the invention, the facing photosensitive resin layer and opposite photosensitive resin layer composing the photosensitive resin layer may be in contact, or a non-photosensitive resin layer lacking photosensitivity may be situated between them. For example, as shown in FIG. 4, the photosensitive film may have a first interlayer 21 and a second interlayer 22 as non-photosensitive resin layers between the first photosensitive resin layer 2 as a photosensitive resin layer and the second photosensitive resin layer 3 as a photosensitive resin layer. In this photosensitive film 110, the first interlayer 21 and second interlayer 22 preferably employ resins that dissolve in the developing solution.

A photosensitive film having no protective film according to the invention has an adhesive force PT (units: N/m) between the surface of the support film opposite the surface on which the first photosensitive resin layer is formed (opposite support surface) and the nth photosensitive resin layer as the uppermost layer laminated n layers from the support film (opposite photosensitive resin layer) that is lower than the adhesive force PU (units: N/m) between the support film and the first photosensitive resin layer contacting with the support film (the facing photosensitive resin layer), in order to facilitate release of the aforementioned nth photosensitive resin layer from the support film when the photosensitive film is wound into a roll, and when it is restored to a sheet form during lamination. When the photosensitive resin layer has such an n-layer structure, the value of (PU/PT) preferably satisfies the condition represented by any of inequalities (1) to (4) above. As a method of achieving a smaller PT than PU, and especially a method of producing a (PU/PT) value that satisfies a condition represented by any of inequalities (1) to (4) above, there may be mentioned the first to third methods explained above for the photosensitive film 100 illustrated in FIGS. 1 and 2. When the photosensitive resin layer has an n-layer structure, n is preferably 2-8, more preferably 2-5 and most preferably 2.

The support film preferably has an m-layer structure with m number of laminated layers, and preferably the front and back sides (the two surfaces, i.e. the aforementioned one surface and the opposite support surface on the side opposite it) have approximately the same adhesive force. Here, m is preferably an integer of 1-5. By using such a support film it is possible to form a photosensitive resin layer on either the front or back side when producing the photosensitive film. This will also facilitate reuse of the support film. In addition, the maximum surface roughness of each of the front and back sides of the support film is preferably no greater than 3000 nm (3.0 μm), more preferably no greater than 2000 nm (2.0 μm) and most preferably no greater than 1000 nm (1.0 μm). This will facilitate formation of the photosensitive resin layer on the support film, while also preventing generation of air voids during lamination of the photosensitive film.

The protective film-less type photosensitive film of the invention may be in the form of a roll or a sheet. However, the cross-section of the photosensitive film preferably has a repeating structure comprising the support film, the first photosensitive resin layer and the nth photosensitive resin layer in order from the lowest value of n.

When the protective film-less type photosensitive film of the invention is laminated on a board and exposed by radiation such as UV through a pattern mask and then passed through a developing step, preferably at least the opposite photosensitive resin layer of the photosensitive film of the invention that contacts with the board (the layer furthest from the support film of the photosensitive resin layer) remains as a pattern on the board.

The material and shape of the board will differ depending on whether it is for a printed circuit board, a lead frame, a display or the like. The photosensitive film of the invention may be used as a sand blast mask film, a cover lay film or a solder resist film.

The constituent elements of the protective film-less type photosensitive film described above will now be explained.

As examples of support films to be used for the invention there may be mentioned films made of polyethylene terephthalate, polyethylene naphthalate, polyester, polyethylene, polypropylene, polystyrene, polyimide, polyvinyl chloride, nylon, polycarbonate, polyethylenecellulose triacetate, vinyl chloride and vinylidene chloride copolymer, cellophane and the like.

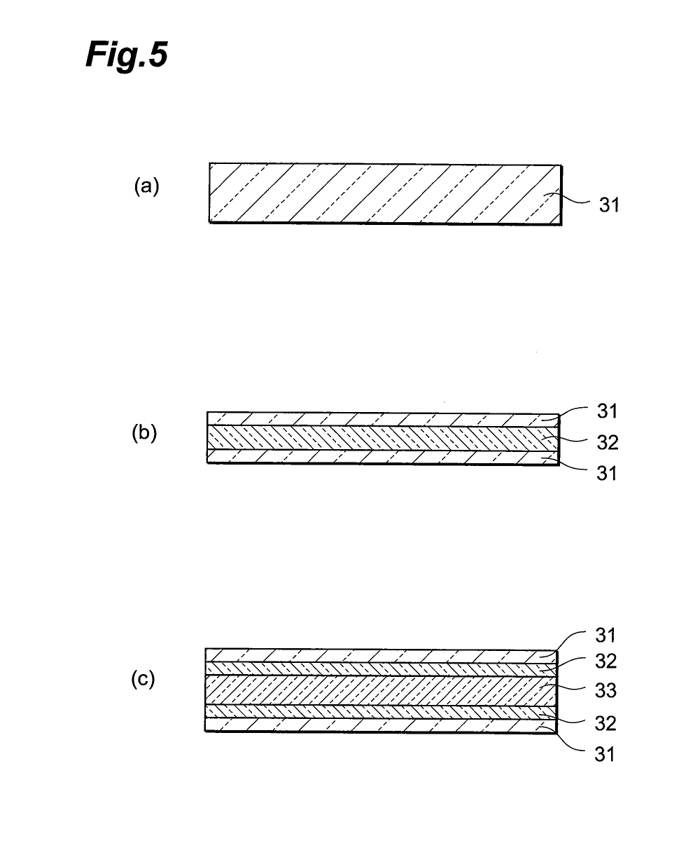

As m-layer structures having m layers of the support film laminated (where is m is preferably an integer of 1-5), there may be mentioned a structure wherein a PET film is laminated on at least one side of a PET film, a structure composed of a lubricant-containing film 31 incorporating a lubricant, as shown in FIG. 5(a), a structure wherein the aforementioned lubricant-containing film 31 is formed on both sides of a lubricant-free film 32 containing little or no lubricant, as shown in FIG. 5(b), a structure wherein the aforementioned lubricant-free film 32 and lubricant-containing film 31 are formed on either side of a functional film 33 incorporating an adhesive or antistatic agent, as shown in FIG. 5(c), a nylon-based multilayer film, a PE-based multilayer film, a super high gas barrier film, a silicone-coated film, a plastic metal composite material, an aluminum vapor deposited film, nylon/PET, PP/PET, PE/PET, PET/AL/PE, PET/AL/PP and PET/polyolefin/AL/PP laminated films, and the like. As mentioned above, these preferably have the same adhesive force on front and back.

Since these support films must be subsequently removable from the photosensitive resin layer, they must not be of a material or surface treated in a manner that would prevent their removal. By limiting the maximum surface roughness of both the front and back sides of the support film to no greater than 3000 nm (3.0 μm), it is possible to prevent generation of air voids during coating of the photosensitive resin layer and lamination of the photosensitive film of the invention. The thickness of the support film is preferably 1-100 μm, more preferably 4-50 μm and most preferably 8-30 μm. If the thickness is less than 1 μm, problems such as reduced mechanical strength and tearing of the photosensitive film during coating will tend to occur, and if it exceeds 100 μm, the resolution will tend to be lower and the cost increased.

The facing photosensitive resin layer and opposite photosensitive resin layer composing the photosensitive resin layer may be publicly known layers, and for example, there may be mentioned a layer comprising a photosensitive resin composition containing (A) a binder polymer, (B) a photopolymerizing compound having at least one polymerizable ethylenic unsaturated group in the molecule and (C) a photopolymerization initiator.

As examples for the (A) binder polymer there may be mentioned acrylic-based resins, styrene-based resins, epoxy-based resins, amide-based resins, amide/epoxy-based resins, alkyd-based resins, phenol-based resins and the like. An acrylic-based resin is preferred from the standpoint of alkali developing properties. These may be used alone or in combinations of two or more.

The (A) binder polymer may be produced, for example, by radical polymerization of a polymerizable monomer. As examples of polymerizable monomers there may be mentioned styrene, polymerizable styrene derivatives such as vinyltoluene, α-methylstyrene, p-methylstyrene, p-ethylstyrene, p-methoxystyrene, p-ethoxystyrene, p-chlorostyrene and p-bromostyrene, acrylamides such as diacetoneacrylamide, acrylonitrile, vinyl alcohol esters such as vinyl-n-butyl ether, (meth)acrylic acid alkyl esters, (meth)acrylic acid tetrahydrofurfuryl ester, (meth)acrylic acid dimethylaminoethyl ester, (meth)acrylic acid diethylaminoethyl ester, (meth)acrylic acid glycidyl ester, 2,2,2-trifluoroethyl (meth)acrylate, 2,2,3,3-tetrafluoropropyl (meth)acrylate, (meth)acrylic acid, α-bromo(meth)acrylic acid, α-chlor(meth)acrylic acid, β-furyl(meth)acrylic acid, β-styryl(meth)acrylic acid, maleic acid, maleic anhydride, maleic acid monoesters such as monomethyl maleate, monoethyl maleate and monoisopropyl maleate, fumaric acid, cinnamic acid, α-cyanocinnamic acid, itaconic acid, crotonic acid, propiolic acid and the like.

As examples of (meth)acrylic acid alkyl esters there may be mentioned methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate and the like. These may be used alone or in combinations of two or more.

The (A) binder polymer preferably contains a carboxyl group from the viewpoint of the alkali developing property, and for example, it may be produced by radical polymerization of a carboxyl group-containing polymerizable monomer with another polymerizable monomer. Methacrylic acid is preferred as a carboxyl group-containing polymerizable monomer.

The binder polymer in the opposite photosensitive resin layer furthest from the support film (the nth photosensitive resin layer) preferably contains styrene or a styrene derivative as a polymerizable monomer from the viewpoint of reducing adhesive force with the support film. Also, the binder polymer in the first photosensitive resin layer coated on the support film (the facing photosensitive resin layer) preferably does not contain styrene or a styrene derivative as a polymerizable monomer from the viewpoint of improving adhesive force with the support film.

The polymerizable monomer of the binder polymer in the opposite photosensitive resin layer furthest from the support film (the nth photosensitive resin layer) contains styrene or a styrene derivative as a copolymerizing component preferably at 0.1-45 mass %, more preferably at 1-40 mass %, even more preferably at 1.5-35 mass % and most preferably at 2-30 mass %. If the content is less than 0.1 mass % the adhesive force with the support film cannot be reduced and adhesiveness with the board will tend to be poor, and if it exceeds 45 mass % the peeling strips will increase in size and the release time will tend to be lengthened.

The (A) binder polymer has a weight-average molecular weight of preferably 20,000-200,000 and more preferably 30,000-150,000. A weight-average molecular weight of less than 20,000 will tend to result in lower developing solution resistance and film strength, while greater than 200,000 will tend to lower the resolution. When the support film has a photosensitive resin layer composed of a plurality of layers, the weight-average molecular weight of the binder polymer in the opposite photosensitive resin layer furthest from the support film (the nth photosensitive resin layer) is preferably 20,000-100,000, more preferably 25,000-80,000 and most preferably 30,000-60,000 from the viewpoint of reducing adhesive force with the support film. The weight-average molecular weight of the binder polymer in the first photosensitive resin layer coated on the support film is preferably 40,000-200,000, more preferably 50,000-150,000 and most preferably 60,000-100,000 from the viewpoint of improving adhesive force with the support film.

Such binder polymers are used alone or in combinations of two or more. As examples of binder polymers when two or more are used in combination, there may be mentioned two or more binder polymers composed of different copolymerizable components, two or more binder polymers with different weight-average molecular weights, and two or more binder polymers with different dispersibilities.

The weight-average molecular weight is determined according to measurement by gel permeation chromatography, and is calculated from a calibration curve drawn using standard polystyrene.

As examples for the (B) photopolymerizing compound there may be mentioned compounds obtained by reacting α,β-unsaturated carboxylic acids with polyhydric alcohols, bisphenol A-based (meth)acrylate compounds such as 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane and 2,2-bis(4-((meth)acryloxypolyethoxypolypropoxy)phenyl)propane, compounds obtained by reacting α,β-unsaturated carboxylic acids with glycidyl group-containing compounds, urethane monomers such as urethane bond-containing (meth)acrylate compounds, phthalic acid-based compounds such as nonylphenoxypolyalkyleneoxy (meth)acrylate, γ-chloro-β-hydroxypropyl-β′-(meth)acryloyloxyethyl-o-phthalate and β-hydroxyalkyl-β′-(meth)acryloyloxyalkyl-o-phthalate, and (meth)acrylic acid alkyl esters but bisphenol A-based (meth)acrylate compounds and urethane bond-containing (meth)acrylate compounds are preferred as essential components. They may also be used alone or in combinations of two or more.

As examples of the aforementioned compounds obtained by reacting α,β-unsaturated carboxylic acids with polyhydric alcohols there may be mentioned polyethylene glycol di(meth)acrylate having 2-14 ethylene groups, polypropylene glycol di(meth)acrylate having 2-14 propylene groups, polyethylenepolypropylene glycol glycol di(meth)acrylate having 2-14 ethylene groups and 2-14 propylene groups, trimethylolpropane di(meth)acrylate, trimethylolpropane tri(meth)acrylate, EO-modified trimethylolpropane tri(meth)acrylate, PO-modified trimethylolpropane tri(meth)acrylate, EO,PO-modified trimethylolpropane tri(meth)acrylate, tetramethylolmethane tri(meth)acrylate, tetramethylolmethane tetra(meth)acrylate, dipentaerythritol penta(meth)acrylate, dipentaerythritol hexa(meth)acrylate, and the like.

As examples of 2,2-bis(4-((meth)acryloxypolyethoxy)phenyl)propane compounds there may be mentioned 2,2-bis(4-((meth)acryloxydiethoxy)phenyl)propane, 2,2-bis(4-((meth)acryloxytriethoxy)phenyl)propane, 2,2-bis(4-((meth)acryloxytetraethoxy)phenyl)propane, 2,2-bis(4-((meth)acryloxypentaethoxy)phenyl)propane, 2,2-bis(4-((meth)acryloxyhexaethoxy)phenyl)propane, 2,2-bis(4-((meth)acryloxyheptaethoxy)phenyl)propane, 2,2-bis(4-((meth)acryloxyoctaethoxy)phenyl)propane, 2,2-bis(4-((meth)acryloxynonaethoxy)phenyl)propane, 2,2-bis(4-((meth)acryloxydecaethoxy)phenyl)propane, 2,2-bis(4-((meth)acryloxyundecaethoxy)phenyl)propane, 2,2-bis(4-((meth)acryloxydodecaethoxy)phenyl)propane, 2,2-bis(4-((meth)acryloxytridecaethoxy)phenyl)propane, 2,2-bis(4-((meth)acryloxytetradecaethoxy)phenyl)propane, 2,2-bis(4-((meth)acryloxypentadecaethoxy)phenyl)propane and 2,2-bis(4-((meth)acryloxyhexadecaethoxy)phenyl)propane, among which 2,2-bis(4-(methacryloxypentaethoxy)phenyl)propane is commercially available as BPE-500 (trade name of Shin-Nakamura Chemical co., Ltd.), and 2,2-bis(4-((methacryloxypentadecaethoxy)phenyl)propane is commercially available as BPE-1300 (trade name of Shin-Nakamura Chemical Co., Ltd.). They may also be used alone or in combinations of two or more.

As examples of 2,2-bis(4-((meth)acryloxypolyethoxypolypropoxy)phenyl)propane compounds there may be mentioned 2,2-bis(4-((meth)acryloxydiethoxyoctapropoxy)phenyl)propane, 2,2-bis(4-((meth)acryloxytetraethoxytetrapropoxy)phenyl)propane, 2,2-bis(4-((meth)acryloxyhexaethoxyhexapropoxy)phenyl)propane and the like. They may also be used alone or in combinations of two or more.

As examples of the aforementioned urethane monomer there may be mentioned addition products of (meth)acrylic monomers having OH groups at the β-position with diisocyanate compounds such as isophorone diisocyanate, 2,6-toluenediisocyanate, 2,4-toluenediisocyanate and 1,6-hexamethylenediisocyanate, as well as tris((meth)acryloxytetraethylene glycolisocyanate)hexamethylene isocyanurate, EO-modified urethane di(meth)acrylates, EO,PO-modified urethane di(meth)acrylates, and the like. As an example of an EO-modified urethane di(meth)acrylate there may be mentioned UA-11 by Shin-Nakamura Chemical Co., Ltd. As an example of an EO,PO-modified urethane di(meth)acrylate there may be mentioned UA-13 by Shin-Nakamura Chemical Co., Ltd. EO stands for ethylene oxide, and an EO-modified compound has a block structure of ethyleneoxy groups. PO stands for propylene oxide, and a PO-modified compound has a block structure of propyleneoxy groups.

As nonylphenoxypolyalkyleneoxy (meth)acrylate compounds there may be mentioned nonylphenoxypolyethyleneoxy acrylate, nonylphenoxypolyethyleneoxy methacrylate, nonylphenoxypolypropyleneoxy acrylate, nonylphenoxypolypropyleneoxy methacrylate, butylphenoxypolyethyleneoxy acrylate, butylphenoxypolyethyleneoxy methacrylate, butylphenoxypolypropyleneoxy acrylate, butylphenoxypolypropyleneoxy methacrylate and the like.

As examples of nonylphenoxypolyethyleneoxy acrylate compounds there may be mentioned nonylphenoxytetraethyleneoxy acrylate, nonylphenoxypentaethyleneoxy acrylate, nonylphenoxyhexaethyleneoxy acrylate, nonylphenoxyheptaethyleneoxy acrylate, nonylphenoxyoctaethyleneoxy acrylate, nonylphenoxynonaethyleneoxy acrylate, nonylphenoxydecaethyleneoxy acrylate, nonylphenoxyundecaethyleneoxy acrylate and the like.

As examples of nonylphenoxypolyethyleneoxy methacrylate compounds there may be mentioned nonylphenoxytetraethyleneoxy methacrylate, nonylphenoxypentaethyleneoxy methacrylate, nonylphenoxyhexaethyleneoxy methacrylate, nonylphenoxyheptaethyleneoxy methacrylate, nonylphenoxyoctaethyleneoxy methacrylate, nonylphenoxynonaethyleneoxy methacrylate, nonylphenoxydecaethyleneoxy methacrylate, nonylphenoxyundecaethyleneoxy methacrylate, and the like. They may also be used alone or in combinations of two or more.

As examples for the (C) photopolymerization initiator there may be mentioned benzophenone, N,N′-tetraalkyl-4,4′-diaminobenzophenones such as N,N′-tetramethyl-4,4′-diaminobenzophenone (Michler's ketone), aromatic ketones such as 2-benzyl-2-dimethylamino-1-(4-morpholinophenyl)-butanone-1,2-methyl-1-[4-(methylthio)phenyl]-2-morpholino-propanone-1, quinones such as alkylanthraquinones, benzoin ether compounds such as benzoinalkyl ethers, benzoin compounds such as benzoin and alkylbenzoins, benzyl derivatives such as benzyldimethylketal, 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer and 2-(p-methoxyphenyl)-4,5-diphenylimidazole dimer, acridine derivatives such as 9-phenylacridine and 1,7-bis(9,9′-acridinyl)heptane, as well as N-phenylglycine, N-phenylglycine derivatives, coumarin-based compounds and the like.

Substituents on two of the aryl groups of 2,4,5-triarylimidazole may be identical to yield a symmetrical compound, or they may be different to yield an asymmetrical compound. From the viewpoint of adhesiveness and sensitivity, a 2,4,5-triarylimidazole dimer is preferred. These may be used alone or in combinations of two or more.

The content of the (A) binder polymer is preferably 40-80 parts by mass with respect to 100 parts by mass as the total of component (A) and component (B). If the content is less than 40 parts by mass the photocured product may be too fragile, tending to result in inferior coatability when used as a photosensitive resin layer, while if it is greater than 80 parts by mass the photosensitivity will tend to be insufficient.

The content of the (B) photopolymerizing compound is preferably 20-60 parts by mass with respect to 100 parts by mass as the total of component (A) and component (B). If the content is less than 20 parts by mass the photosensitivity will tend to be insufficient, and if it is greater than 60 parts by mass the photocured product will tend to be fragile.

The content of the (C) photopolymerization initiator is preferably 0.1-20 parts by mass with respect to 100 parts by mass as the total of component (A) and component (B). If the content is less than 0.1 part by mass the photosensitivity will tend to be insufficient, and if it is greater than 20 parts by mass the absorption on the surface of the composition during exposure will increase, tending to result in insufficient interior photocuring.

The photosensitive resin composition may, if necessary, contain a photopolymerizing compound having at least one cationic polymerizable cyclic ether group in the molecule, a cationic polymerization initiator, a dye such as malachite green, a photochromic agent such as tribromophenylsulfone or leuco crystal violet, a thermal development inhibitor, a plasticizer such as p-toluenesulfonamide, a pigment, filler, antifoaming agent, flame retardant, stabilizer, tackifier, leveling agent, release promoter, antioxidant, aromatic, imaging agent, thermal crosslinking agent or the like, at about 0.01-20 parts by mass each with respect to 100 parts by mass as the total of component (A) and component (B). These may be used alone or in combinations of two or more.

The photosensitive resin composition may, if necessary, be coated as a solution in a solvent such as methanol, ethanol, acetone, methyl ethyl ketone, methylcellosolve, ethylcellosolve, toluene, N,N-dimethylformamide or propyleneglycol monomethyl ether, or a mixture of such solvents, at a solid content of about 30-60 mass %.

The overall thickness of the photosensitive resin layer will differ depending on the purpose, but the post-drying thickness is preferably 1-200 μm, more preferably 1-100 μm, even more preferably 2-50 μm and most preferably 3-25 μm. A thickness of less than 1 μm will tend to hamper industrial coating, while a thickness of greater than 200 μm will tend to result in insufficient sensitivity, thus impairing the photocuring property of the resist base.

The thickness of each layer of the photosensitive resin layer is each independently preferably 1-75 μm, more preferably 1-50 μm, even more preferably 1-35 μm, yet more preferably 2-25 μm and most preferably 3-15 μm.

A photosensitive resin layer is generally obtained, for example, by coating and drying a photosensitive resin composition on a support film.

The coating may be accomplished by a publicly known method using, for example, a roll coater, comma coater, gravure coater, air knife coater, die coater, bar coater, spray coater or the like. The drying may be accomplished at 70-150° C. for about 5-30 minutes. The amount of residual organic solvent in the photosensitive resin layer is preferably no greater than 2 mass % from the viewpoint of preventing diffusion of the organic solvent in subsequent steps.

Coating of a multilayer photosensitive resin layer may be accomplished by simultaneous coating (multilayer coating) or successive coating, according to the publicly known methods mentioned above. For example, when the photosensitive resin layer consists of two layers as shown in FIG. 2, there may be mentioned (1) a method of laminating the first photosensitive resin layer 2 on the support film 1 and then laminating the second photosensitive resin layer 3, and (2) a method of simultaneously laminating the first photosensitive resin layer 2 and second photosensitive resin layer 3 on the support film 1. Method (2) is preferred from the viewpoint of workability.

A photosensitive resin layer having a multilayer structure may be obtained simultaneously by multilayer extrusion molding.

The method by which the photosensitive film comprising a multilayer photosensitive resin layer coated on the support film is wound around a core is not particularly restricted, but the following method is preferred from the viewpoint of reducing air bubble inclusion and creases. Winding of the photosensitive film is accomplished by applying linear pressure to the winding core by a press roller situated parallel to the widthwise direction of the winding axis. The pressure is preferably 100-500 kg/m, more preferably 150-450 kg/m and most preferably 200-400 kg/m. The surface material of the press roller is preferably an elastic material and especially rubber, and the hardness is preferably 40-90 degrees. The tension during winding of the photosensitive film is preferably 10-30 kg/m, more preferably 12-25 kg/m and most preferably 14-20 kg/m. In order to maintain a constant tension against the photosensitive film from beginning to end of the winding, it is preferred to control the tension according to the winding diameter. The pressure during winding of an ordinary photosensitive film having a protective film is no greater than 50 kg/m, and the tension is about 10 kg/m.

If the photosensitive resin layer comprises at least a facing photosensitive resin layer and an opposite photosensitive resin layer, it is not necessary for all of the layers to be photosensitive resin layers, and non-photosensitive resin layers without photosensitivity may be included. In such cases, the facing photosensitive resin layer is situated on the side of photosensitive resin layer nearest the support film, and the opposite resin layer is situated at the side furthest from the support film.

The non-photosensitive resin layer is not particularly restricted so long as it employs a resin that dissolves in the developing solution. For example, the non-photosensitive resin layer may be composed of a resin composition comprising a carboxyl group-containing polymer and comprising no photopolymerization initiator.

The protective film-less type photosensitive film of the invention is stored after being wound onto a cylindrical winding core, for example. The material of the cylindrical winding core may be, for example, a paper tube, wooden tube, plastic tube, metal tube or the like, but it is preferably a metal tube from the viewpoint of withstanding pressure during winding. When the photosensitive film is wound on such a winding core for storage, it is preferably wound with the support film on the outermost side. An edge separator is preferably situated at the edge of the photosensitive film roll from the viewpoint of edge protection, while from the viewpoint of preventing edge fusion, the edge separator is preferably moisture-proof. The packaging method is preferably one that involves bundling in a black sheet with low moisture permeability. As examples for the winding core there may be mentioned plastics such as polyethylene resin, polypropylene resin, polystyrene resin, polyvinyl chloride resin, ABS resin (acrylonitrile-butadiene-styrene copolymer) and the like. The photosensitive film of the invention may also be stored in a sheet form.

When a resist pattern is formed on a board using the aforementioned photosensitive film, the method of laminating the photosensitive film on the board is preferably a method of lamination by contacting bonding the photosensitive film to a circuit-forming board with a pressure of about 0.1-1 MPa (about 1-10 kgf/cm²) while heating to about 70-130° C., and the lamination is preferably carried out under reduced pressure. The surface of the laminated board is not particularly restricted, but is ordinarily a metal surface.

The laminated photosensitive film is then exposed to radiation (active light rays) through a negative or positive mask pattern for image formation. The light source for the active light rays may be a publicly known light source such as, for example, a carbon arc lamp, mercury vapor arc lamp, high pressure mercury lamp, xenon lamp or the like, which efficiently emits ultraviolet rays or visible light. When the support film is impermeable to radiation (active light rays), the exposure to radiation (active light rays) through the negative or positive mask pattern for image formation is performed after releasing the support film.

When the support film remains on the photosensitive resin layer after exposure, the support film is removed and then development is performed by removing the unexposed sections by wet development using a developing solution such as an aqueous alkali solution, aqueous developing solution or organic solvent, or dry development, to produce a resist pattern. As examples of aqueous alkali solutions there may be mentioned a 0.1-5 mass % sodium carbonate dilute solution, a 0.1-5 mass % potassium carbonate dilute solution or a 0.1-5 mass % sodium hydroxide dilute solution. The pH of the aqueous alkali solution is preferably in the range of 9-11, and the temperature is adjusted as appropriate for the developing property of the photosensitive resin layer. The aqueous alkali solution may also contain added surfactants, antifoaming agents, organic solvents and the like. The developing system may be, for example, a dip system, a spray system, or one that employs brushing, slapping or the like.

Post-development treatment may consist of heating at about 60-250° C. or exposure at about 0.2-10 mJ/cm² if necessary for further curing of the resist pattern.

For etching of the metal surface after development there may be employed an etching solution such as a copper(II) chloride solution, ferric chloride solution, alkali etching solution or the like.

For manufacture of a printed circuit board using a photosensitive film of the invention, the surface of the circuit-forming board is treated by a publicly known process such as etching or plating using the developed resist pattern as a mask. As examples of plating methods there may be mentioned copper plating, solder plating, nickel plating, gold plating and the like. The resist pattern is then released, for example, with an aqueous solution of stronger alkalinity than the aqueous alkali solution used for development. The strongly alkaline aqueous solution may be, for example, a 1-10 mass % sodium hydroxide aqueous solution or a 1-10 mass % potassium hydroxide aqueous solution. The releasing system may be, for example, a dipping system, spraying system or the like. The printed circuit board on which the resist pattern has been formed may be a multilayer printed circuit board, and it may also have small through-holes.

When a photosensitive film roll of the invention is laminated on a board and exposed to light under the conditions described above, the number of air voids with sizes of 80 μm or greater on the exposed photosensitive resin layer and circuit-forming board (copper-clad laminate) surface is preferably as small as possible from the viewpoint of reducing wiring pattern defects and wire breakage. In order to avoid practical problems, the number of air voids should be no greater than 10/m², preferably no greater than 5/m² and most preferably 0/m².

### EXAMPLES

The present invention will now be explained in greater detail by preferred examples, with the understanding that the invention is in no way limited to these examples.

(Fabrication of Photosensitive Resin Layer-Forming Coating Solution)

The materials listed in Table 1 were combined to obtain a first photosensitive resin layer-forming coating solution. The materials listed in Table 2 were also combined to obtain a second photosensitive resin layer-forming coating solution. Components (A) listed in Tables 1 and 2 are polymer components, and these polymers were used as solutions diluted with a mixed solution of methyl cellosolve/toluene=6/4 (mass ratio), prepared to a non-volatile (solid) content of 40 mass % for component (A) in Table 1 and a non-volatile (solid) content of 43 mass % for component (A) in Table 2. The weight-average molecular weight (Mw) was measured by gel permeation chromatography (GPC), with calculation based on a standard polystyrene calibration curve. The GPC conditions were as follows.

(GPC Conditions)

Pump: Hitachi L-6000 (Hitachi, Ltd.),

Column: Gelpack GL-R420+Gelpack GL-R430+Gelpack GL-R440 (total: 3) (all trade names of Hitachi Chemical Co., Ltd.),

Eluant: Tetrahydrofuran

Measuring temperature: 25° C.

Flow rate: 2.05 mL/min

Detector: Hitachi L-3300 RI (Hitachi, Ltd.)

TABLE 1

| Component | Compound | Content | |
|---|---|---|---|
| Component (A) | Methacrylic acid/methyl | 150 | g |
| | methacrylate/butyl | (60 g solid | |
| | methacrylate = 22/50/28 | portion) | |
| | (mass ratio), Mw = 100,000 | | |
| Component (B) | 2,2-bis(4-(Methacryloxy- | 30.0 | g |
| | pentadecaethoxy)phenyl)propane | | |
| | EO-modified nonylphenyl acrylate | 10.0 | g |
| | (EO chain repeating units: 8) | | |
| Component (C) | N,N′-Tetraethyl-4,4′- | 0.15 | g |
| | diaminobenzophenone | | |
| | 2-(o-Chlorophenyl)-4,5- | 3.0 | g |
| | diphenylimidazole dimer | | |
| Other | Leuco crystal violet | 0.5 | g |
| components | Malachite green | 0.05 | g |
| | p-Toluenesulfonamide | 4.0 | g |
| Solvent | Acetone | 10.0 | g |
| | Toluene | 10.0 | g |
| | Methanol | 3.0 | g |
| | N-Dimethylformamide | 3.0 | g |

(Mw: weight-average molecular weight, EO: ethylene oxide)

TABLE 2

| Component | Compound | Content | |
|---|---|---|---|
| Component (A) | Methacrylic acid/methyl | 140 | g |
| | methacrylate/butyl | (60 g solid | |
| | methacrylate/styrene = | portion) | |
| | 25/35/15/25 (mass ratio), | | |
| | Mw = 70,000 | | |
| Component (B) | 2,2-bis(4-(Methacryloxy- | 30.0 | g |
| | pentadecaethoxy)phenyl)propane | | |
| | EO-modified nonylphenyl acrylate | 10.0 | g |
| | (EO chain repeating units: 8) | | |
| Component (C) | N,N′-Tetraethyl-4,4′- | 0.15 | g |
| | diaminobenzophenone | | |
| | 2-(o-Chlorophenyl)-4,5- | 3.0 | g |
| | diphenylimidazole dimer | | |
| Other | Leuco crystal violet | 0.5 | g |
| components | Malachite green | 0.05 | g |
| | p-Toluenesulfonamide | 4.0 | g |
| Solvent | Acetone | 10.0 | g |
| | Toluene | 10.0 | g |
| | Methanol | 3.0 | g |
| | N-Dimethylformamide | 3.0 | g |

### Reference Example 1

A coating solution for formation of the first photosensitive resin layer and a coating solution for formation of the second photosensitive resin layer were each separately applied onto a 16 μm-thick PET film (G2-16, trade name of Teijin, Ltd.) and dried with hot air at 90° C. for 10 minutes, to obtain a photosensitive film composed of the first photosensitive resin layer having a post-drying thickness of 25 μm and PET film and a photosensitive film composed of the second photosensitive resin layer with a post-drying thickness of 25 μm and PET film.

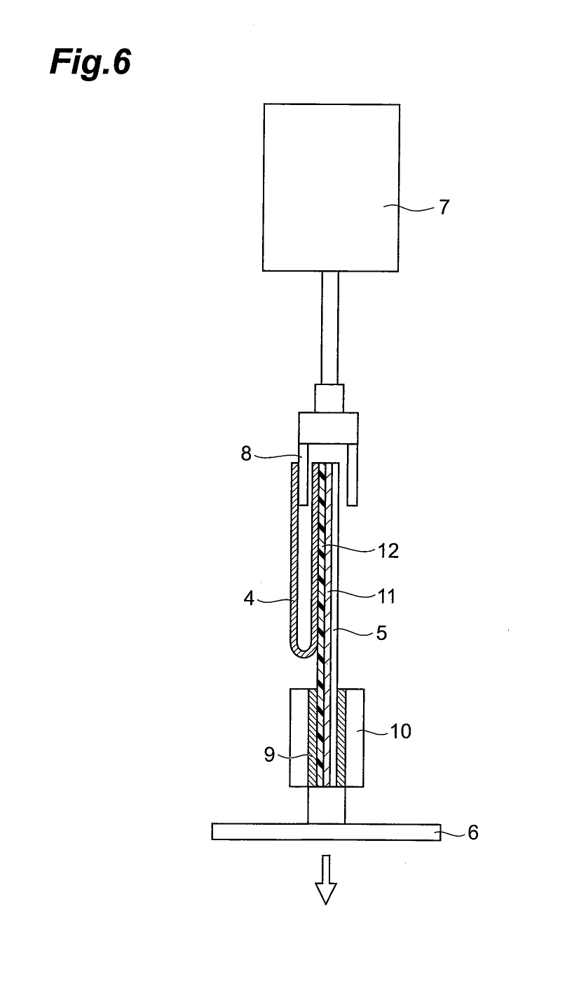

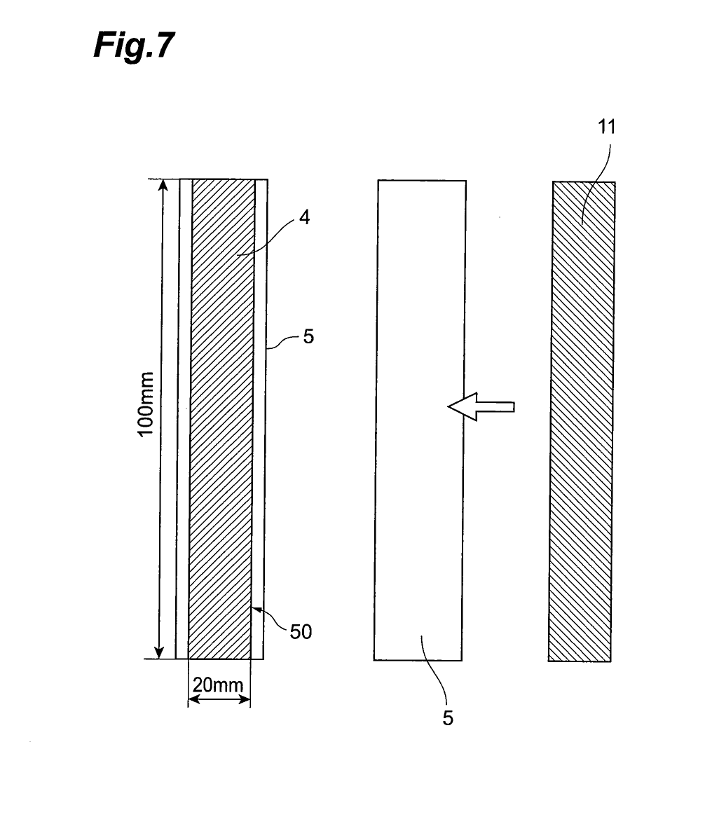

The obtained photosensitive films were allowed to stand for 30 minutes in an environment at 23±3° C., 60±5% RH (23° C.). A test piece comprising each obtained photosensitive film was mounted on a jig as shown in FIG. 6, the vertically adjustable table was lowered at a speed of 2 m/min, and the adhesive force between the PET film and first photosensitive resin layer and the adhesive force between the PET film and second photosensitive resin layer were measured with a rheometer (RT-3010D-CW by Rheotech) in an environment of 23±3° C., 60±5% RH (23° C.). The test piece was prepared in the manner shown in FIG. 7. Specifically, on one side of a copper-clad laminate (MCL-E-61, trade name of Hitachi Chemical Co., Ltd.) which comprised a glass epoxy material laminated on both sides of a copper foil (35 μm thickness) there was attached double-sided tape 11 (NICETACK, trade name of Nichiban Co., Ltd.) in the form of two 5 mm-wide pieces or one 10 mm-wide piece, and then a 20 mm×100 mm photosensitive film 50 was attached thereover on the photosensitive resin layer 12 side and measurement was conducted when peeling off the PET film 4. In FIG. 6, the PET film 4 is mounted with a clamp 8, and the clamp 8 is attached to a load 7. One end of the copper-clad laminate 5 was held between a board clamp 10 provided with a rubber seal 9, and the board clamp 10 was mounted on the vertically adjustable table 6. The adhesive forces measured in this manner are listed in Table 3.

### Reference Example 2

The coating solution for formation of the second photosensitive resin layer was evenly applied onto a 20 μm-thick polyethylene film (PE film) as the protective film and dried with hot air at 90° C. for 10 minutes to obtain a photosensitive film composed of the second photosensitive resin layer having a post-drying thickness of 25 μm and PE film. The obtained photosensitive film was allowed to stand for 30 minutes in an environment at 23±3° C., 60±5% RH (23° C.). A test piece of the photosensitive film obtained in this manner was used for measurement of the adhesive force between the PE film and second photosensitive resin layer by the same method as the aforementioned adhesive force measurement 1. The results are shown in Table 3.

TABLE 3

| | | | Reference |
|---|---|---|---|
| | Reference Example 1 | | Example 2 |
| | First | Second | Second |
| | photosensitive | photosensitive | photosensitive |
| | resin layer and | resin layer and | resin layer and PE |
| Parameter | PET film | PET film | film |
| Adhesive force | 7.5 | 1.5 | 1.5 |
| (N/m) | | | |

As shown in Table 3, the adhesive force between the first photosensitive resin layer and PET film was 7.5 N/m. The adhesive force between the second photosensitive resin layer and PET film was 1.5 N/m, which was adhesive force equal to the adhesive force of 1.5 N/m exhibited between the second photosensitive resin layer and PE film. These results demonstrate that when a photosensitive film having a photosensitive resin layer obtained by laminating a first photosensitive resin layer and second photosensitive resin layer and having no protective film is laminated on a board, the PET film and the first photosensitive resin layer do not separate but only the second photosensitive resin layer and PET film separate upon unwinding from the film roll, and therefore the photosensitive resin layer can be easily laminated on the board.

### Example 1

A coating solution for formation of the first photosensitive resin layer and a coating solution for formation of the second photosensitive resin layer were evenly applied onto a 16 μm-thick polyethylene terephthalate film (PET film) by simultaneous coating, and dried with hot air at 90° C. for 10 minutes to obtain a photosensitive film as shown in FIG. 1 and FIG. 2.

The application was performed so that the post-drying thicknesses of the first photosensitive resin layer and second photosensitive resin layer were 10 μm and 15 μm respectively (total thickness of first photosensitive resin layer and second photosensitive resin layer: 25 μm).

Next, the copper surfaces of a copper-clad laminate (MCL-E-61, trade name of Hitachi Chemical Co., Ltd.) which comprised a glass epoxy material laminated on both sides of a copper foil (35 μm thickness) were polished using a polishing machine (Sankei Co., Ltd.) with a #600 equivalent brush, and after washing with water and drying with an air stream, the obtained copper-clad laminate was heated to 80° C., and the aforementioned photosensitive film was laminated on the copper surface using a high-temperature laminator (HLM-3000 by Hitachi Chemical Co., Ltd.) at a temperature of 110° C., a pressure of 0.3 MPa and a laminating speed of 3 m/min.

One hundred such copper-clad laminates were laminated, and within 30 minutes from lamination they were exposed at 100 mJ/cm² using an exposure apparatus (HMW-201B, Orc Manufacturing Co., Ltd.) equipped with a high pressure mercury lamp. The number of air voids generated during this time was counted using a 100× magnification microscope, and was recorded as the air void generation. The results are shown in Table 4.

### Reference Example 3

The second photosensitive resin layer was laminated onto 100 copper-clad laminates in the same manner as Example 1, except that the photosensitive film of Reference Example 2 was used and the lamination was performed while releasing the protective film, and within 30 minutes from lamination, exposure was performed at 100 mJ/cm² using an exposure apparatus (HMW-201B, Orc Manufacturing Co., Ltd.) equipped with a high pressure mercury lamp. The air void generation is shown in Table 4.

### Reference Example 4

A photosensitive film for Reference Example 4 was obtained in the same manner as the photosensitive film of Reference Example 2, except that the protective film was changed from a 20 μm-thick polyethylene film to a 20 μm-thick polypropylene film. The obtained photosensitive film was used for lamination of a second photosensitive resin layer on 100 copper-clad laminates in the same manner as Example 1, except that the lamination was carried out while releasing the protective film. The air void generation is shown in Table 4.

TABLE 4

| | | Reference | Reference |
|---|---|---|---|
| Parameter | Example 1 | Example 3 | Example 4 |
| Protective | None | Polyethylene | Polypropylene |
| film | | film | film |
| Air void | 0 | 20 | 0 |
| generation | | | |
| (/100 films) | | | |

Next, a non-exposed copper-clad laminate fabricated during evaluation of the air void generation was exposed at 60 mJ/cm² using an HMW-201B exposure apparatus (product of Orc Manufacturing Co., Ltd.) equipped with a high pressure mercury lamp. This was spray-developed with a 1 mass % sodium carbonate aqueous solution at 30° C. and then washed and dried, and subjected to a printed circuit board circuit-forming process.

It was confirmed that wiring boards of comparable levels were formed when using the photosensitive film of Example 1 and when using the photosensitive films of Reference Examples 3 and 4.

### Example 2

The photosensitive film of Example 1 was used for lamination of a photosensitive film on a copper-clad laminate made of the aforementioned material having through-holes formed therein, and the subsequent steps up to the developing step were carried out but with a lengthened developing time, in order to evaluate the hole tearability as an additional property. The results are shown in Table 5.

### Reference Example 5

The photosensitive film of Reference Example 2 was used for lamination of a photosensitive film on a copper-clad laminate made of the aforementioned material having through-holes formed therein, while releasing the protective film, and the hole tearability was evaluated in the same manner as Example 3. The results are shown in Table 5.

### Reference Example 6

A photosensitive film for Reference Example 6 was obtained in the same manner as Reference Example 2, except that the thickness of the second photosensitive resin layer in the photosensitive film of Reference Example 2 was changed to 35 μm. The hold tearability was evaluated in the same manner as Reference Example 5, except for using the obtained photosensitive film. The results are shown in Table 5.

TABLE 5

| | | Evaluation sample | | | | | | | | |
|---|---|---|---|---|---|---|---|---|---|---|
| | | Example 2 | | | Reference Example 5 | | | Reference Example 6 | | |
| | | (Photosensitive resin | | | (Photosensitive resin | | | (Photosensitive resin | | |
| | | layer thickness: 25 μm) | | | layer thickness: 25 μm) | | | layer thickness: 35 μm) | | |
| Parameter | Times developed | 3 | 5 | 10 | 3 | 5 | 10 | 3 | 5 | 10 |

| | | | | | | | | | |
|---|---|---|---|---|---|---|---|---|---|
| Round hole (φ6 mm) | 0 | 0 | 0 | 6 | 10 | 16 | 0 | 4 | 9 |
| (/10 holes) | | | | | | | | | |
| Round hole (φ3 mm) | 0 | 0 | 0 | 0 | 0 | 3 | 0 | 0 | 0 |
| (/10 holes) | | | | | | | | | |
| Three continuous holes | 0 | 0 | 2 | 8 | 15 | 25 | 0 | 6 | 15 |
| (large)*¹ | | | | | | | | | |
| (/10 holes) | | | | | | | | | |
| Three continuous holes | 0 | 0 | 0 | 5 | 6 | 12 | 0 | 0 | 4 |
| (small)*² | | | | | | | | | |
| (/10 holes) | | | | | | | | | |

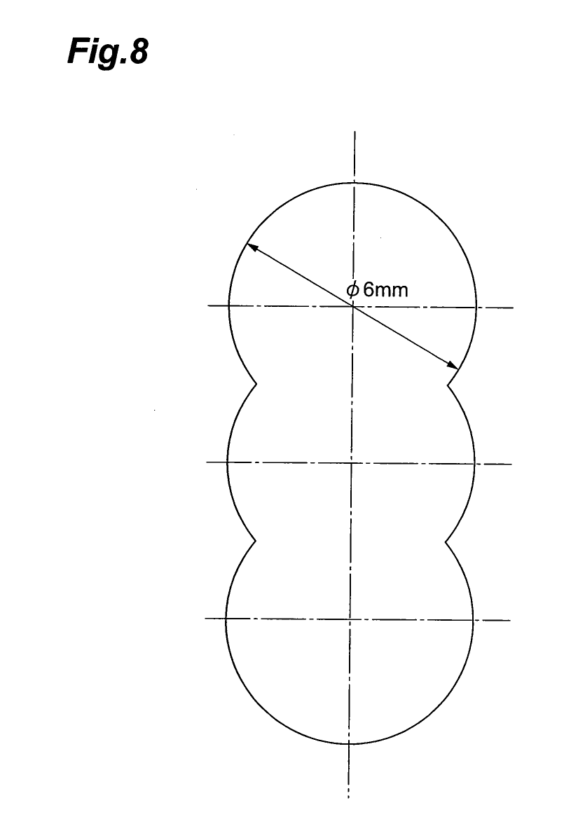

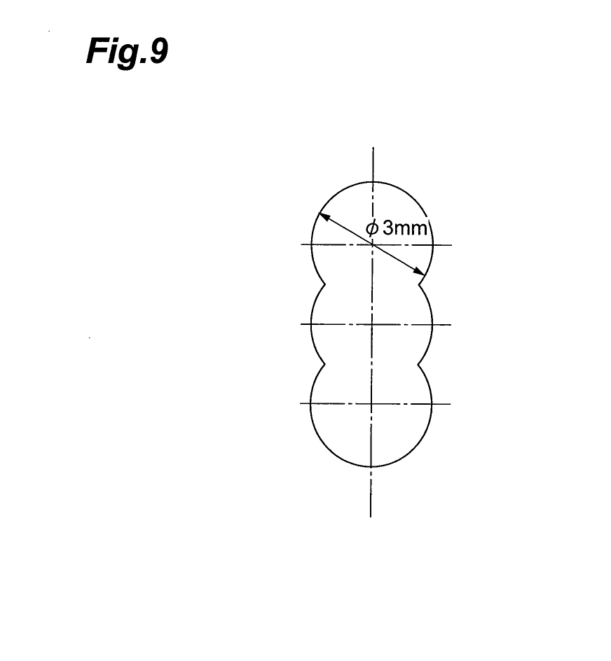

*¹Three continuous holes (large): φ6 mm continuous holes (see FIG. 8)
*²Three continuous holes (small): φ3 mm continuous holes (see FIG. 9)

Each developing time shown in Table 5 (developing time for each development) is twice the minimum time (minimum developing time) for attaching the photosensitive film onto the board and developing without exposure.

The compositions of the photosensitive resin layers (second photosensitive resin layers) of Reference Example 5 (photosensitive resin layer thickness: 25 μm) and Reference Example 6 (photosensitive resin layer thickness: 35 μm) are the compositions shown in Table 2.

Each board used for evaluation had 30 holes opened per board, and the average of five photosensitive film-laminated boards was taken.

### Example 3

The waste production per 1000 m² when using the photosensitive film of Example 1 is shown in Table 6.

### Reference Example 7

The waste production per 1000 m² when using the photosensitive film of Reference Example 2 is shown in Table 6.

TABLE 6

| | | Reference |
|---|---|---|
| Parameter | Example 3 | Example 7 |
| Waste production | 1.8 | 4 |
| (kg/1000 m²) | | |

As shown in Table 6, the photosensitive film of Example 3 allows waste production to be reduced below half with respect to the prior art product (Reference Example 7).

(Production of Polymers A to F)

As component (A), there were produced polymers A to F having the compositions listed in Table 7, exhibiting the weight-average molecular weights and glass transition temperatures also listed in the table. These polymers were used as solutions prepared to a non-volatile (solid) content of 50 mass % by dilution with a mixed solution of methyl cellosolve/toluene=6/4 (mass ratio).

TABLE 7

| | | | Glass |
|---|---|---|---|
| | | Weight-average | transition |
| Component (A) | Composition | molecular wt. | temp. (° C.) |
| Polymer A | Methacrylic acid/methyl | 70,000 | 91.1 |
| | methacrylate/butyl | | |
| | methacrylate = 23/50/27 | | |
| Polymer B | Methacrylic acid/methyl | 80,000 | 110.4 |
| | methacrylate/ethyl | | |
| | methacrylate = 25/50/25 | | |
| Polymer C | Methacrylic acid/methyl | 60,000 | 45.2 |
| | methacrylate/ethyl | | |
| | acrylate/butyl | | |
| | acrylate = 17/50/10/23 | | |
| Polymer D | Methacrylic acid/methyl | 50,000 | 101.0 |
| | methacrylate/butyl | | |
| | methacrylate/styrene = | | |
| | 20/50/15/15 | | |
| Polymer E | Methacrylic acid/methyl | 40,000 | 124.8 |
| | methacrylate/styrene = | | |
| | 30/50/20 | | |
| Polymer F | Methacrylic acid/methyl | 35,000 | 110.5 |
| | methacrylate/ethyl | | |
| | acrylate/styrene = | | |
| | 25/40/5/30 | | |

### Example 4

A 16 μm-thick polyethylene terephthalate (PET) film (G2-16, product of Teijin, Ltd.) was prepared as a support film. Also, 110 g (solid portion: 55 g) of polymer A as component (A) and the components listed in Table 8 (component (B), component (C), other components and solvent) were combined, and stirred to uniformity to prepare a coating solution for formation of a first photosensitive resin layer. Similarly, 110 g (solid portion: 55 g) of polymer D as component (A) and the components listed in Table 8 were combined and stirred to uniformity to prepare a coating solution for formation of a second photosensitive resin layer. The contents of the components listed in Table 8 were as shown in the same table.

The coating solution for formation of the first photosensitive resin layer was evenly applied onto the support film to a post-drying thickness of 5 μm, and dried for 10 minutes with a hot air convection drier at 90° C. to form a first photosensitive resin layer. Next, the coating solution for formation of the second photosensitive resin layer was evenly applied onto the first photosensitive resin layer to a post-drying thickness of 10 μm, and dried for 10 minutes with a hot air convection drier at 90° C. to form a second photosensitive resin layer. This produced the photosensitive film for Example 4 having the construction shown in FIG. 2.

### Examples 5-9

Photosensitive films for Examples 5 to 9 were obtained in the same manner as Example 4, having the construction shown in FIG. 2, except that the coating solution for formation of the first photosensitive resin layer and the coating solution for formation of the second photosensitive resin layer had the compositions listed in Table 9.

### Comparative Example 1

A 16 μm-thick polyethylene terephthalate (PET) film (G2-16, product of Teijin, Ltd.) was prepared as a support film. Also, 110 g (solid portion: 55 g) of polymer D as component (A) and the components listed in Table 8 were combined and stirred to uniformity to prepare a coating solution for formation of a photosensitive resin layer. The contents of the components listed in Table 8 were as shown in the same table.

The coating solution for formation of the photosensitive resin layer was evenly applied onto the PET film to a post-drying thickness of 15 μm and dried for 10 minutes with a hot air convection drier at 90° C. to obtain a photosensitive element comprising a single photosensitive resin layer.

TABLE 8

| Component | Compound | Content | |
|---|---|---|---|
| Component (B) | 2,2-bis(4-(Methacryloxy- | 20.0 | g |
| | pentadecaethoxy)phenyl)propane | | |
| | EO-modified nonylphenyl acrylate | 5.0 | g |
| | (Average repeating | | |
| | units of oxyethylene groups: 8) | | |
| | Polypropyleneglycol diacrylate*¹ | 10.0 | g |
| Component (C) | N,N′-Tetraethyl-4,4′- | 0.15 | g |
| | diaminobenzophenone | | |
| | 2-(o-Chlorophenyl)-4,5- | 3.0 | g |
| | diphenylimidazole dimer | | |
| Other | Leuco crystal violet | 0.5 | g |
| components | P-Toluenesulfonamide | 3.0 | g |
| | Malachite green | 0.05 | g |
| Solvent | Acetone | 10.0 | g |
| | Toluene | 10.0 | g |
| | Methanol | 3.0 | g |

*¹APG-400 ™, Shin-Nakamura Chemical Co., Ltd.

TABLE 9

| | | Second photosensitive |
|---|---|---|
| | First photosensitive resin layer- | resin layer-forming |
| | forming coating solution | coating solution |
| Example 4 | Polymer A (55 g solid portion) + | Polymer D (55 g solid |
| | Table 8 component | portion) + Table 8 |
| | | component |
| Example 5 | Polymer B (55 g solid portion) + | Polymer E (55 g solid |
| | Table 8 component | portion) + Table 8 |
| | | component |
| Example 6 | Polymer C (55 g solid portion) + | Polymer F (55 g solid |
| | Table 8 component | portion) + Table 8 |
| | | component |
| Example 7 | Polymer A (55 g solid portion) + | Polymer F (55 g solid |
| | Table 8 component | portion) + Table 8 |
| | | component |
| Example 8 | Polymer B (55 g solid portion) + | Polymer E (55 g solid |
| | Table 8 component | portion) + Table 8 |
| | | component |
| Example 9 | Polymer C (55 g solid portion) + | Polymer D (55 g solid |
| | Table 8 component | portion) + Table 8 |
| | | component |
| Comp. Ex. 1 | Polymer D (55 g solid portion) + | — |
| | Table 8 component | |

[Measurement of Adhesive Force]

The adhesive force between the first photosensitive resin layer or second photosensitive resin layer and the PET film for each of Examples 4 to 6 was measured by the same method as in Reference Example 1. The results are shown in Table 10.

TABLE 10

| Photosensitive resin layer | Adhesive strength (N/m) |
|---|---|
| First photosensitive resin layer of Example 4 | 4.5 |
| First photosensitive resin layer of Example 5 | 4.0 |
| First photosensitive resin layer of Example 6 | 5.0 |
| Second photosensitive resin layer of Example 4 | 1.5 |
| Second photosensitive resin layer of Example 5 | 0.8 |
| Second photosensitive resin layer of Example 6 | 1.0 |

[Fabrication of Photosensitive Film-Attached Copper-Clad Laminate]

The copper surfaces of a copper-clad laminate (MCL-E-61, trade name of Hitachi Chemical Co., Ltd.) which comprised a glass epoxy material laminated on both sides of a copper foil (35 μm thickness) were subjected to dipping treatment in 150 g of sodium persulfate at 25° C. for 1 minute, and then washed with water and dried with an air stream. The obtained copper-clad laminate was heated to 80° C., and each of the photosensitive films prepared in Examples 4 to 9 and Comparative Example 1 was laminated onto the copper surface using a high-temperature laminator (HLM-3000, product of Hitachi Chemical Co., Ltd.) at a temperature of 110° C., a pressure of 0.3 MPa and a laminating speed of 3 m/min, with the photosensitive resin layer in contact with the copper surface. A photosensitive film-attached copper-clad laminate was obtained in this manner.

[Evaluation of Photosensitivity]

The aforementioned photosensitive film-attached copper-clad laminate was used to evaluate the photosensitivity by the following procedure. First, a Stouffer 21-step tablet was placed on the photosensitive film as a negative, and an exposure apparatus (HMW-1201, product of Orc Manufacturing Co., Ltd.) equipped with a high pressure mercury lamp was used for exposure at 100 mJ/cm².

Next, the polyethylene terephthalate support film was released and a 1 mass % sodium carbonate aqueous solution at 30° C. was sprayed for twice the minimum developing time for each (50% break point) to remove the unexposed sections. The number of steps of the step tablet of the photocured film formed on the copper-clad laminate was then measured to evaluate the photosensitivity of the photosensitive resin layer. The results are shown in Table 11. The photosensitivity is indicated by the number of steps of the step tablet, with a higher step tablet step number representing higher photosensitivity.

[Evaluation of Resolution]

The aforementioned photosensitive film-attached copper-clad laminate was used to evaluate the resolution by the following procedure. First, a phototool with a Stouffer 21-step tablet and a phototool having a wiring pattern with a line width/space width of 6/6-47/47 (units: μm) as a negative for evaluation of resolution were adhered to the photosensitive film, and an exposure apparatus (HMW-1201 by Orc Manufacturing Co., Ltd.) equipped with a high pressure mercury lamp was used to provide an energy dose for a residual step number of 5.0 after development of the Stouffer 21-step tablet. Development was then carried out by the same method for evaluation of the photosensitivity, and the smallest value for the space width between line widths that allowed clean removal of the unexposed section by developing treatment was recorded as the resolution. The results are shown in Table 11. A smaller value for the resolution is more satisfactory.

[Evaluation of Adhesiveness]

The aforementioned photosensitive film-attached copper-clad laminate was used to evaluate the adhesiveness by the following procedure. First, a phototool with a Stouffer 21-step tablet and a phototool having a wiring pattern with a line width/space width of 6/400-47/400 (units: μm) as a negative for evaluation of resolution were adhered to the photosensitive film, and an exposure apparatus (HMW-1201 by Orc Manufacturing Co., Ltd.) equipped with a high pressure mercury lamp was used to provide an energy dose for a residual step number of 7.0 after development of the Stouffer 21-step tablet. Development was then carried out by the same method for evaluation of the photosensitivity, and evaluation was based on the smallest value for the space width between line widths that allowed clean removal of the unexposed section by developing treatment. The results are shown in Table 11. A smaller value for the adhesiveness is more satisfactory.

TABLE 11

| | Example | Example | Example | Example | Example | Example | Comp. Ex. |
|---|---|---|---|---|---|---|---|
| | 4 | 5 | 6 | 7 | 8 | 9 | 1 |
| Photosensitivity | 5 | 5 | 5 | 5 | 5 | 5 | 5 |
| (ST = X/21) | | | | | | | |
| Resolution (μm) | 12 | 14 | 8 | 12 | 14 | 10 | 10 |
| Adhesiveness (μm) | 10 | 8 | 12 | 12 | 8 | 10 | 12 |

As clearly seen by the results in Table 11, the photosensitive films of Examples 4 to 9 produced results equivalent to Comparative Example 1 in terms of photosensitivity, resolution and adhesiveness.

[Fabrication of Photosensitive Film Roll]

### Example 10

A 300 mm-wide photosensitive film having the composition of Example 4 was wound around a cylindrical plastic tube with an outer diameter of 3.5 inches using a press roller with a rubber surface material situated parallel to the widthwise direction of the winding axis, applying a linear pressure of 200 kg/m against the plastic tube and winding 200 m at a tension of 15 kg/m, to obtain a photosensitive film roll. The obtained photosensitive film roll had an outer diameter of 12 cm and was satisfactory with no inclusion of air bubbles or creases.

### Example 11

A photosensitive film roll was obtained in the same manner as Example 10, except that a 300 mm-wide photosensitive film having the composition of Example 9 was used. The obtained photosensitive film roll had an outer diameter of 12 cm and was satisfactory with no inclusion of air bubbles or creases.

### Comparative Example 2

A 20 μm-thick polyethylene film (GF-3, product of Tamapoly Co., Ltd.) was laminated as a protective film on the photosensitive resin layer of the photosensitive film obtained in Comparative Example 1, to obtain a photosensitive film for Comparative Example 2. This photosensitive film was wound around a 300 mm-wide cylindrical plastic tube with an outer diameter of 3.5 inches using a press roller with a rubber surface material situated parallel to the widthwise direction of the winding axis, applying a linear pressure of 50 kg/m against the plastic tube and winding 200 m at a tension of 10 kg/m. This yielded a photosensitive film roll for Comparative Example 2. The obtained photosensitive film roll had an outer diameter of 14 cm and was satisfactory with no inclusion of air bubbles or creases.

### Comparative Example 3

A photosensitive film roll was obtained in the same manner as Comparative Example 2, except that a 20 μm-thick biaxial stretched polypropylene film (E-200C, product of Oji Paper Co., Ltd.) was used as the protective film. The obtained photosensitive film roll had an outer diameter of 14 cm and was satisfactory with no inclusion of air bubbles or creases.

### Reference Example 8

A 300 mm-wide photosensitive film having the composition of Example 4 was wound around a cylindrical plastic tube with an outer diameter of 3.5 inches using a press roller with a rubber surface material situated parallel to the widthwise direction of the winding axis, applying a linear pressure of 50 kg/m against the plastic tube and winding 200 m at a tension of 10 kg/m, to obtain a photosensitive film roll. The obtained photosensitive film roll had inclusion of air bubbles, as well as creases.

[Measurement of Air Voids]

The photosensitive film rolls of Examples 10 and 11, Comparative Examples 2 and 3 and Reference Example 8 were allowed to stand for 10 days in an environment at 23±3° C., 60±5% RH (23° C.). Next, the copper surfaces of a copper-clad laminate (MCL-E-61, trade name of Hitachi Chemical Co., Ltd.) which comprised a glass epoxy material laminated on both sides of a copper foil (35 μm thickness) were subjected to dipping treatment in a 2% aqueous sulfuric acid solution and then washed with water and dried with warm air at 30° C. Ten of the obtained copper-clad laminates were each allowed to stand for 10 minutes in an oven at 80° C., and the aforementioned photosensitive film roll was laminated onto the copper surface using a high temperature laminator (HLM-3000, product of Hitachi Chemical Co., Ltd.) at a temperature of 110° C., a pressure of 0.3 MPa and a laminating speed of 3 m/min. During lamination of the photosensitive film of each of the photosensitive film rolls, it was confirmed the photosensitive resin layer had been laminated on the copper surface without residue of the photosensitive resin layer on the roll. Next, within 30 minutes after lamination, the photosensitive film was irradiated with an exposure dose of 100 mJ/cm² using an exposure apparatus (Model EXM-1201, mercury short arc lamp) by Orc Manufacturing Co., Ltd. The number of air voids of 80 μm or greater generated between the photosensitive resin layer and the copper-clad laminate surface after exposure was measured using a microscope at 100× magnification. The results are shown in Table 12.

TABLE 12

| | Exam- | Exam- | Comp. | Comp. | Ref. |
|---|---|---|---|---|---|
| | ple | ple | Ex. | Ex. | Ex. |
| | 10 | 11 | 2 | 3 | 8 |
| Photosensitive | 15 | 15 | 15 | 15 | 15 |
| resin layer | | | | | |
| thickness (μm) | | | | | |
| Protective film | — | — | poly- | poly- | — |
| | | | ethylene | propylene | |
| | | | film | film | |
| Number of | 10 | 5 | 600 | 200 | Unmeasurable |
| air voids | | | | | due to creases |
| generated (/m²) | | | | | in |
| | | | | | photosensitive |
| | | | | | film |

### INDUSTRIAL APPLICABILITY

As explained above, the present invention can provide a protective film-less type photosensitive film with properties that have been unobtainable with conventional photosensitive films. A protective film-less type can also reduce air void generation and waste production during lamination onto boards. Moreover, since a longer photosensitive film roll product can be wound with the same mass without changing the rolling diameter, it is possible to reduce the mounting frequency of the photosensitive film on the laminating apparatus, and thereby minimize loss due to adjustment and the like and improve yield and productivity.

1. A photosensitive film comprising a photosensitive resin layer on a support film,
wherein the photosensitive resin layer is prepared by laminating two or more layers including a facing photosensitive resin layer having a facing surface that faces one surface of the support film and an opposite photosensitive resin layer having an opposing surface on the side of the photosensitive resin layer opposite the facing surface, and
wherein the photosensitive film has no protective film on the photosensitive resin layer and
can be wound up into a roll.

2. A photosensitive film according to claim 1,
wherein the one surface of the support film contacts with the facing surface of the facing photosensitive resin layer, and
wherein the adhesive force PU (units: N/m) between the one surface of the support film and the facing surface of the facing photosensitive resin layer and the adhesive force PT (units: N/m) between the opposite support surface on the side of the support film opposite the one surface and the opposing surface of the opposite photosensitive resin layer, satisfy the condition represented by inequality 1 below.
1.5≦(PU/PT)≦10.0 (1)

3. A photosensitive film according to claim 1,
wherein the facing photosensitive resin layer and opposite photosensitive resin layer each comprise a binder polymer, and
wherein the binder polymer in the opposite photosensitive resin layer has a higher glass transition temperature (Tg) than the binder polymer in the facing photosensitive resin layer.

4. A photosensitive film according to claim 1,
wherein the facing photosensitive resin layer and opposite photosensitive resin layer each comprise a binder polymer, and
wherein the binder polymer in the opposite photosensitive resin layer contains styrene or a styrene derivative as a copolymerizing component.

5. A photosensitive film according to claim 1,
wherein the facing photosensitive resin layer and opposite photosensitive resin layer each comprise a binder polymer, and
wherein the binder polymer in the opposite photosensitive resin layer has a lower weight-average molecular weight than the binder polymer in the facing photosensitive resin layer.

6. A photosensitive film according to claim 1, wherein the support film consists of a single layer or a plurality of laminated layers.

7. A photosensitive film according to claim 1, wherein both sides of the support film have a maximum surface roughness of no greater than 3000 nm.

8. A photosensitive film according to claim 1, wherein the thickness of each layer composing the photosensitive resin layer is 1-75 μm.

9. A photosensitive film according to claim 1, wherein two or more of the layers composing the photosensitive resin layer are obtained simultaneously by multilayer coating or multilayer extrusion molding.

10. A photosensitive film laminate obtained by laminating a photosensitive film according to claim 1.

11. A photosensitive film roll obtained by winding a photosensitive film according to claim 1 into a roll form around a core.

12. A photosensitive film roll according to claim 11, wherein after the photosensitive resin layer of the photosensitive film roll has been laminated on a copper-clad laminate under conditions with a laminating temperature of 110° C., a pressure of 0.3 MPa and a laminating speed of 3 m/min, and the entire surface of the photosensitive resin layer has been irradiated with active light rays of 100 mJ/cm² or greater within 30 minutes, the number of air voids of diameter 80 μm or greater generated between the photocured photosensitive resin layer and the copper-clad laminate surface is no greater than 10/m².

13. A photosensitive film roll according to claim 11, wherein the number of layers composing the photosensitive resin layer is 2-8.
